(19) United States
(12) Patent Application Publication
(10) Pub. No.: US 2012/0256651 A1
(43) Pub. Date: Oct. 11, 2012

(54) TEST STRUCTURE FOR PARALLEL TEST IMPLEMENTED WITH ONE METAL LAYER

(75) Inventors: MANJUL BHUSHAN, Hopewell Junction, NY (US); Mark B. Ketchen, Hadley, MA (US)

(73) Assignee: INTERNATIONAL BUSINESS MACHINES CORPORATION, Armonk, NY (US)

(21) Appl. No.: 13/082,934

(22) Filed: Apr. 8, 2011

(51) Int. Cl. G01R 31/00; G01R 31/02

(52) U.S. Cl. 324/756.01; 324/537

(57) ABSTRACT

An integrated test circuit includes pads of a padset for testing multiple device under test units (MDUTs). The MDUTs each include devices under test (DUTs). A first integrated test circuit metal layer is patterned to connect the pads to N MDUTs such that a first set of pads are employed for enabling testing of each MDUT and a second set of pads are designated for testing individual DUTs associated with the enabled MDUTs such that N parallel tests may be concurrently performed.

### BACKGROUND

1. Technical Field

The present invention relates to semiconductor device testing and more particularly to test structures and methods of testing which employ parallel tests using parallel wiring of multiple device under test units.

2. Description of the Related Art

In complementary metal oxide semiconductor (CMOS) technology characterization, current-voltage (I-V) characteristics of metal oxide field effect transistors (MOSFETs) are routinely measured. In early technology development, device development is carried out in parallel with metal stack development on independent short-loop test vehicles. Hence, only a single metal layer may be available for wiring the MOSFETs for electrical parametric tests. In product manufacturing, it is preferable to carry out MOSFET characterization as early in the process cycle as possible, and test structures in a scribe line on a wafer are designed to be measurable at a first metal layer, M1.

One drawback in implementing test structures at M1 is that significant wiring complexity in the designs is difficult to achieve. Standard test structures are relatively basic, with MOSFETs situated in a space between input/output (I/O) pads. A number of MOSFETs in a test structure macro is limited by a number of I/O pads, and a large number of such macros are required to cover various types of MOSFET offerings of different dimensions and physical layouts. This uses up precious Silicon space on the wafer.

The test time for I-V characterization is long even with a parallel test approach as each macro comprises only 10 to 20 MOSFETs in a standard 1×25 I/O pad array and only one or a small number of MOSFETs can be simultaneously measured.

FIGS. 1 and 2 show two of many possible pad configurations. These include a discrete FET macro with isolated n-FETs (FIG. 1) and a discrete FET macro with shared source (S) and drain (D) pads and a common gate pad (G). In FIG. 1, pads (1-12) are illustratively shown to accommodate three n-FETs 13. If the macro includes 25 pads, it can accommodate six n-FETs. While all six devices 13 can, in principle, be measured in parallel, the overall efficiency is very low with only six devices under test (DUT) per macro.

In FIG. 2, pads (1-12) are illustratively shown to accommodate ten FETs 13. For a full 25 pad macro, 23 (with no substrate contact) or 22 (with a substrate contact) MOSFETS can be accommodated. However, realistically only a single MOSFET can be characterized at a time due to biasing/isolation constraints.

A multi-port test structure with one-dimensional arrays has been implemented with a 5-bit decoder, which selects one of the MOSFETs in an array to be tested at a time. Although this design has a high degree of area and test efficiency, it may be low yielding very early in a technology development cycle because of the complexity of the decoder.

### SUMMARY

An integrated test circuit includes pads of a padset for testing multiple device under test units (MDUTs). The MDUTs each include a plurality of devices under test (DUTs). A first integrated test circuit metal layer is patterned to connect the pads to N MDUTs such that a first set of pads are employed for testing the N MDUTs and a second set of pads are designated for testing individual DUTs associated with the MDUTs such that N parallel tests may be concurrently performed.

A system for testing integrated circuits includes a plurality of pads of a padset for testing N multiple device under test units (MDUTs), the MDUTs each including a plurality of devices under test (DUTs). Parallel wiring is formed in a first metal layer and is configured to selectively enable each MDUT through a first set of the plurality of pads, the parallel wiring further configured to enable individual DUT tests through a second set of the plurality of pads. A parallel tester is configured to generate signals on the padset such that in conjunction with the parallel wiring, N parallel tests may be concurrently performed.

A method for testing a test structure includes contacting a plurality of pads of a padset for testing multiple device under test units (MDUTs), the MDUTs each including a plurality of devices under test DUTs; generating signals to a first integrated test circuit metal layer patterned to connect the pads to test N MDUTs such that a first set of the plurality of pads are employed for enabling testing of each MDUT and a second set of the plurality of pads are designated for testing individual DUTs associated with the enabled MDUTs; and concurrently performing N parallel tests to test the DUTs.

Another method for testing a test structure includes providing a plurality of pads of a padset for testing multiple device under test units (MDUTs), the MDUTs each including a plurality of devices under test DUTs, and a first integrated test circuit metal layer patterned to connect the pads to N MDUTs such that a first set of the plurality of pads are employed for enabling testing of each MDUT and a second set of the plurality of pads are designated for testing individual DUTs associated with the enabled MDUTs; and concurrently performing N parallel tests to test the DUTs.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a partial padset showing four pads dedicated to testing a single device in accordance with a prior art arrangement;

FIG. 2 is a partial padset showing pad sharing between devices in accordance with another prior art arrangement;

FIG. 3 is a schematic layout of a multiple device under test unit (MDUT) test structure in accordance with one illustrative embodiment having devices under test connected in parallel;

FIG. 4 is a schematic diagram showing a portion of a macro with parallel wiring in a first single metal layer padset and depicting two MDUTs each with ten DUTs in accordance with one illustrative embodiment;

FIG. 5 is a schematic diagram showing a portion of a macro with parallel wiring in a first single metal layer padset and depicting four MDUTs each with ten DUTs in accordance with another illustrative embodiment;

FIG. 6 is a plot showing number of devices under test per macro and number of parallel tests as a function of number of devices under test per MDUT for a 1 by 25 linear padset arrangement;

FIG. 7 is a plot showing number of devices under test per macro and number of parallel tests as a function of number of devices under test per MDUT for a 1 by 50 linear padset arrangement;

FIG. 8 is a schematic diagram of another illustrative device under test that may be employed in accordance with the present principles;

FIG. 9 is a schematic diagram showing a portion a of macro with parallel wiring in a first single metal layer padset and depicting three resistor MDUTs each with six resistor DUTs in accordance with another illustrative embodiment;

FIG. 10 is a block/flow diagram showing a method for testing a test structure in accordance with the present principles; and

FIG. 11 is a block diagram showing a test system setup for testing a wafer in accordance with the present principles.

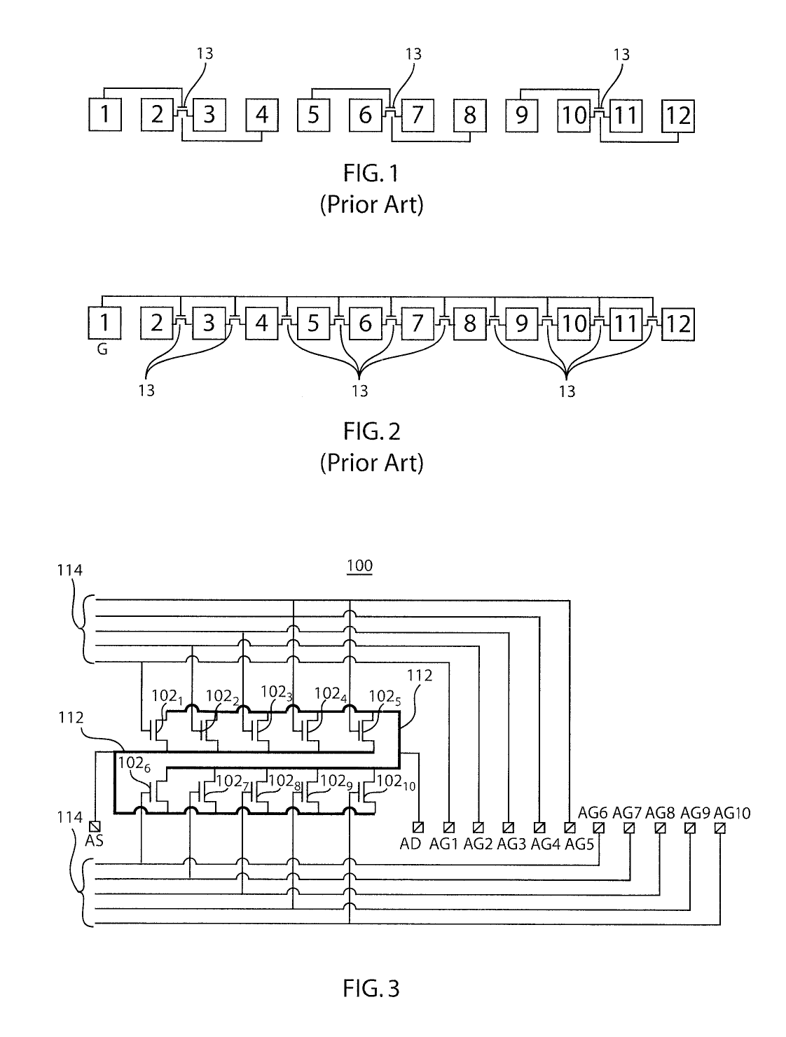

### DETAILED DESCRIPTION OF PREFERRED EMBODIMENTS

In accordance with the present principles, an efficient test structure design for parallel testing is provided. The test structure may be implemented with a single metal layer (e.g., M1). The single metal layer is arranged to permit multiple device under test units (MDUTs) to be tested in parallel. Each MDUT includes a plurality of devices under test (DUTs). The DUTs are connected or arranged to permit individual testing of each DUT. The test structure provides a padset that permits the isolation or parallel testing on one or more MDUTs. The MDUTs are selected by generating appropriate signals to enable or disable the MDUTs. Then, designated pads in the padset are employed to test the individual DUTs. The same designated pads are employed to test the same corresponding DUT in each MDUT. In this way, the designated pads for the individual DUT test are commonly employed by each MDUT test.

In one embodiment, one macro comprises N=10 MDUTs (multiple device under test (DUT) units also referred to as md-units), with M=10 devices (e.g., MOSFETs) wired in parallel in each MDUT. This design can therefore accommodate up to N×M=100 devices (MOSFETs) in a macro with n=25 pads and N MOSFETs can be tested in parallel. A negative bias clamp technique may be employed to enable accurate measurement of source-to-drain current, I_{ds}, in a sub-threshold region. Other measurements are also enabled and contemplated. No decoder is needed for DUT selection.

It should be understood that find numerals 1-25 are reserved for pad labels and will be employed in several different drawings throughout this disclosure. It should also be understood that the padsets may include any number of pads and are not limited to 25.

Referring now to the drawings in which like numerals represent the same or similar elements and initially to FIG. 3, a schematic diagram illustratively shows an MDUT 100 (multiple device under test (DUT) units) with ten n-FETs 102₁-102₁₀ in parallel in accordance with one embodiment. The MDUT 100 includes source (S) and drain (D) terminals of the ten n-FETs 102₁-102₁₀ connected in parallel and gate pads or terminals (AG) which are to be connected to independent I/O pads. The MDUT 100 in this example includes ten n-FETs 102₁-102₁₀ wired in parallel, but may include other elements, preferably all of one kind (e.g., all pFETs, etc.).

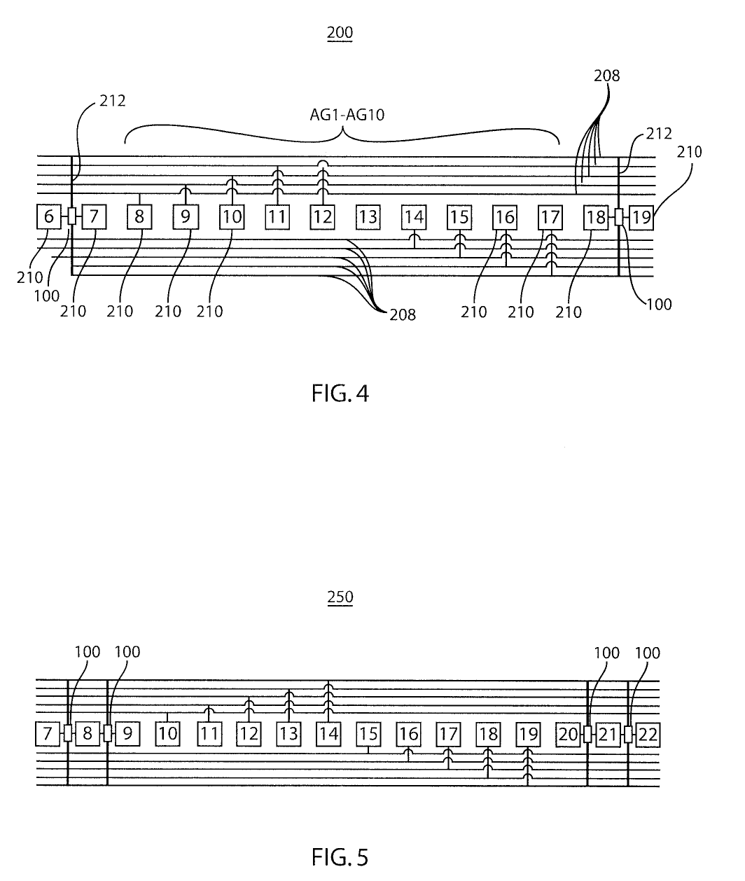

Electrically, the MDUT 100 is a one dimensional array with all n-FETs sharing a common source pad (AS) and a common drain pad (AD). From the perspective of this MDUT 100, each FET 102 has an independent gate pad (AG1-AG10). The gate pad or terminal (AG1-AG10) of each MOSFET 102 in the MDUT 100 is connected to an independent I/O pad (e.g., each of pads 8-17 in FIG. 4). The I/O pads are each shared with a corresponding AG terminal for corresponding DUTs in all other MDUTs in a macro 200 (FIG. 4). In other words, gate terminal AG1 for DUT 102₁ corresponds to pad 8. Pad 8 will be employed to test DUT 102₁ and also will be employed to sequentially test each DUT corresponding to this a first position in each of the other MDUTs. This design may be implemented in a single metal level (e.g., at the M1 metal level).

Measurements are preferably made on one n-FET DUT 102 in each of the MDUTs 100 (multiple MDUTs 100 may be tested simultaneously) while all the other DUTs are biased in an off-state. For example, within an MDUT 100, there is a background current equal to the sum of the I_{off} values of all the DUTs 102 in the off-state. This background current is negligible for I_{ds} measurements in the saturation region but compromises the measurement of I_{off} of an individual DUT.

The current contribution of the devices in the off-state is reduced by applying a negative gate bias, V_{C}. The I_{gl} and gate-induced drain leakage (GIDL) contributions to I_{ds} may be assumed negligible over the useful range of V_{c}. With increasingly negative values of V_{gs}, I_{ds} first decreases following a subthreshold slope (SS) and then starts to increase as the GIDL contribution begins to dominate. The change in slope of an I_{ds}-V_{gs} curve in the negative V_{gs} region is dependent on the relative contributions of S-D diffusion current and GIDL. If the gates of the n-FETs are set at a negative clamp voltage, with V_{gs}=V_{c}, =−0.2 V, for example, the I_{ds} values are lowered by a factor of ˜100 below I_{off}. With 10 nominally identical n-FETs in parallel, the background current would then be 9% of the actual I_{off} of the DUT. The measured I_{off} of the DUT can be corrected by subtracting this amount. In practice, all DUTs in an MDUT are not identical, either by design or because of random variations, and the error in measured I_{off} will be different for each DUT.

Error in measuring I_{ds} in the subthreshold region (V_{gs}≧0) is substantially reduced by making two measurements, together with the use of a correction algorithm. Consider the case with N DUTs in an MDUT. The AG terminals of all DUTs in an MDUT are first biased at V_{C}, and next at a desired test V_{G} (such as V_{gs}=0), and the respective currents I_{all-VC} and I_{all-VG} are measured. We define a ratio, χ, as follows:

$$χ = \frac{{I}_{1 - VC} + {I}_{2 - VC} + … + {I}_{N - VC}}{{I}_{1 - VG} + {I}_{2 - VG} + … + {I}_{N - VG}} = \frac{{I}_{all - VC}}{{I}_{all - VG}} .$$

Here, χ gives a measure of the sub-threshold slope (SS) of all DUTs in an MDUT. Assuming the SS to be the same for all DUTs, the I_{ds} for DUT of index K at a clamp voltage of V_{C} is related to its I_{ds} at a bias V_{G} by the expression: I_{K-VC}=χI_{K-VG}.

The measured I_{ds} of the K^{th} DUT, at a bias of V_{G} (I_{K-VG-meas}), is the sum of its true I_{ds} at a bias of V_{G} (I_{K-VG}) and the I_{ds} values of the remaining (N−1) DUTs at a bias of V_{C}: I_{K-VG-meas}=I_{K-VG}+(I_{all-VC}−I_{VC}), and rearranged to give the corrected value:

$${I}_{K - VG} = \frac{1}{( 1 - χ )} ( {I}_{K - VG - meas} - {I}_{all - VC} ) .$$

With this correction algorithm for I_{ds} in the subthreshold region, accurate I_{ds}-V_{gs} measurements can be made over the entire V_{gs}>0 region. This correction scheme continues to work for DUTs of different types within an MDUT, provided all I_{ds}-V_{gs} characteristics have approximately the same SS values.

In the MDUT macro designs, the number of DUTs in a macro is equal to the number of DUTs per MDUT times the number of MDUTs. The DUTs may be tested serially or in parallel. In case of parallel tests, voltage biases are applied to the S and D terminals of all the MDUTs and the desired G bias to one element in each unit, while all other DUTs are biased at V_{C}. Hence, the number of DUTs tested in parallel is equal to the number of MDUTs in a macro, and the number of sets of such parallel measurements is equal to the number of independent AG pads. The number of DUTs in a macro can be further increased by sharing the S terminal between two adjacent MDUTs. In this approach, the number of S and D pads per MDUT is decreased from 2 to 1.5.

Referring to FIG. 4 with continued reference to FIG. 3, a section of a macro 200 with two MDUTs 100 is illustratively depicted. Additional MDUTs 100 (not shown), each having two I/O pads, may be added to the left and right sides of macro 200 with associated circuitry. With a 1×25 padset three more and units 100 can be added on the right and two plus a substrate contact may be added on the left, to give a total of seven MDUTs, each with 10 DUTs. Other configurations are also completed for FETs and other DUT components. In this embodiment, macro 200 is assumed to include multiple (N=7) n-FET MDUTs 100 configured to share AG pads (AG1-AG10, which comprise pads 8-17). While n=25, only pads 6-19 are indicated in FIG. 4 for simplicity. The additional pads and structures may include appropriate connections.

A pad 25 (not shown) may be a common substrate contact, and seven MDUTs 100 can be accommodated in a macro with a total of N×M=70 n-FETs. As is usually practiced with MOSFET measurements, in general, a single source pad (AS) can be shared between two MDUTs with the current, I_{ds}, measured at drain pads (AD). In one embodiment, ten MDUTs 100 can be accommodated (with no substrate contact) for a total of one hundred n-FETs in the 25 pad macro 250 as illustratively depicted in FIG. 5. Alternatively, ten MDUTs, with nine n-FETs each, can be accommodated along with a common substrate contact. It should be understood that other arrangements with any number of DUTs and MDUTs may be configured in accordance with the present principles.

In FIG. 3, the source and drain of each n-FET 102 are connected to adjacent pads (AS, AD, respectively) with low resistance wide M1 wires 112 so that the parasitic voltage drop is negligible. Since the current through gate leads 114 is extremely small, the resistance can be as high as several kilo-Ohms (kΩ). In FIG. 4, long horizontal gate lead segments 208 above and below the pads 210 may include narrow M1 wires while vertical segments 212 can be M1 wires interrupted by segments of silicided polysilicon or diffusion to underpass other horizontal M1 wires.

A clearance between pads of adjacent macros 200 need only be on the order of tens of microns or less so that no additional space is needed to accommodate the gate lead wiring. Thus, no additional space is required.

One feature of the test structure in accordance with the present principles is that a number of parallel tests (e.g., equal to the number of MDUTs (N=7, 10, etc.) can be carried out simultaneously with a parallel tester. This provides the testing functionality as though the FETs 102 where tested as a one-dimensional addressable array.

A trade-off among the number (M) of MOSFETs in an MDUT, total number of MOSFETs in the macro and the number (N) of MDUTs may be characterized to determine a number of measurements that can be made in parallel.

Referring to FIG. 5, a section of a macro 250 with two pairs of MDUTs 100 is shown. Each pair of MDUTs shares a common source pad (e.g., pad 8 and pad 21). Additional pairs of MDUTs (not shown) having three I/O pads per pair may be added to the left side (e.g., pads 1-6, not shown) and right side (pads 23-25, not shown) of macro 250. In this example, with a 1×25 padset, two more pairs may be added on the left side and one more pair on the right, assuming no substrate contact, to give a total of 10 MDUTs 100, each with 10 DUTs. Other pad configurations are also contemplated.

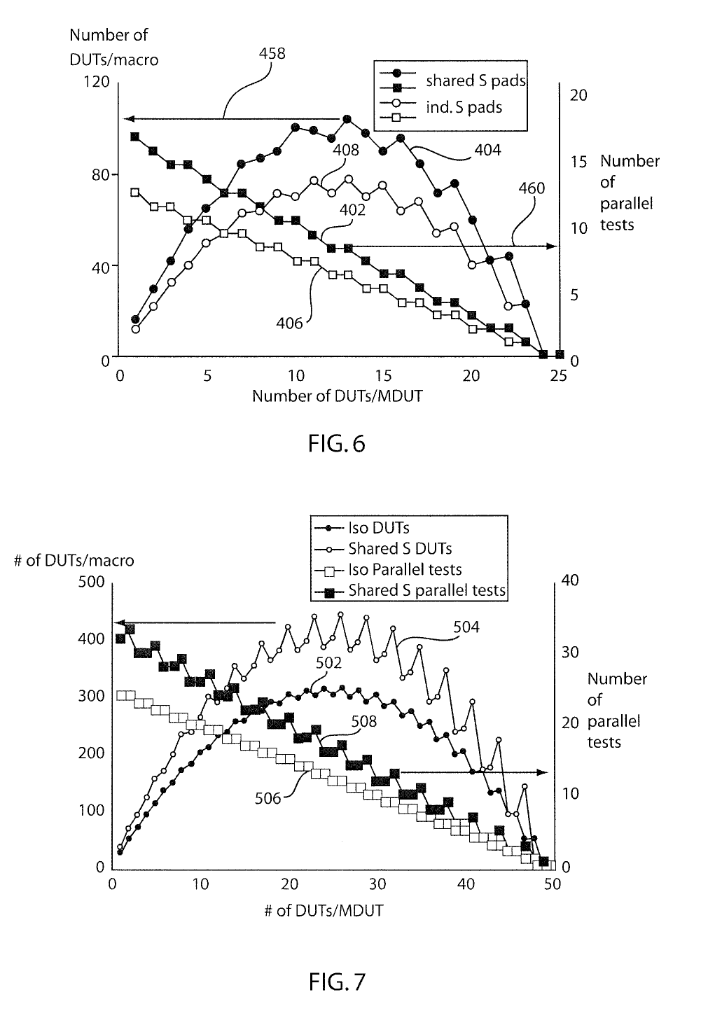

Referring to FIG. 6, a plot shows a number of DUTs/macro (N×M) with 25 I/O pads and a number of tests in parallel (N) both as a function of the number of DUTs/MDUT (M). FIG. 6 depicts this tradeoff with the number of pads n=25 for MDUTs with and without a shared source pad. The plot of FIG. 6 shows plots 402, 404 of DUTs using individual source pads and plots 406, 408 with shared source pad DUTs. A total number of DUTs in each MDUT can be optimized for area and test time efficiency by plotting the number of DUTs per macro and the number of DUTs tested in parallel as a function of the number of DUTs in an MDUT for a standard 1 by 25 padset macro. In the example of FIG. 6, maximum area efficiency is achieved with 13 DUTs per MDUT, and a total of 8 MDUTs which can be tested in parallel (shown by arrows 458 and 460 for a shared source pad (shared S pads) scenario).

FIG. 7 is a similar plot for the case of n=50 is illustratively shown. A number of DUTs/macro (N×M) with 50 I/O pads and a number of tests in parallel (N) are both shown as a function of the number of DUTs/MDUT (M). The plot of FIG. 7 shows isolated DUTs 502, shared source DUTs 504, isolated parallel tests 506 and shared source parallel tests 508. It is observed that for a total number of MOSFETs at or near a maximum, the number of MDUTs N scales with the number of pads, n. The number of MDUTs N is approximately equal to a number of AG inputs such that N=number of MOSFETs/MDUT=number of parallel tests. This can be generalized to a total number of MOSFETs that varies with the number of pads squared (n²).

The optimization is much the same as the area of a rectangle of a given perimeter being maximized for equal length and width and scaling as the square of the perimeter. This approach thus becomes increasingly favorable and attractive as n increases and while escaping the complexity and potential yield loss associated with using a decoder.

Referring again to FIG. 5, during characterization of a ten n-FET MDUT 100, the n-FET (102) to be measured can be exercised by holding its drain-source voltage, V_{ds}, constant and varying its gate voltage, V_{g}, while the gates of the other nine n-FETs are held at ground or some small negative clamp potential V_{C}. With an appropriate value of V_{C} applied (e.g., −0.2 V), the error in a drain-source current, I_{ds}, measurement due to the background current from the unselected MOSFETs is negligible when the selected MOSFET is in the on-state. However, to get the selected MOSFET's I_{ds} in the sub-threshold region (i.e., less than a threshold voltage of the device), a correction may be applied to the measured current. For example, in a special case of 10 nominally identical n-FETs, a good approximation for I_{ds} in the sub-threshold region can be obtained as:

I_{ds}(measured)−0.9 (I_{ds} (with the 10 n-FET array with all AG's set at V_{C}=−0.2 V). Other corrections may also be employed.

This method is generally applicable to cases even where all n-FETs are not nominally identical. In general, with the appropriate parallel tester, N n-FETs are characterized in parallel, each with the same AG input and its I_{ds} being measured at a dedicated AD terminal.

The preceding description concerning n-FETs applies equally to p-FETs with the appropriate polarity reversals. The pad overhead of combining n-FETs and p-FETS in the same macro is high (due to the previously discussed n² behavior), so it is preferable to have only nFETs or only p-FETs in a single macro. While employing a decoder has its advantages, the lack of a decoder greatly lowers design complexity and process yield requirements to demonstrate functionality.

The present principles are applicable for MOSFET characterization but find utility in other applications as well. The present principles may be employed for characterization of other types of DUTs. For example, resistances or other parameters may be characterized. These parameters may be measured for such structures as segments of silicided polysilicon, silicon to metal contacts, etc. It should be further understood that although FETs are described as a DUT, other circuits, components and devices may be employed as DUTs as well.

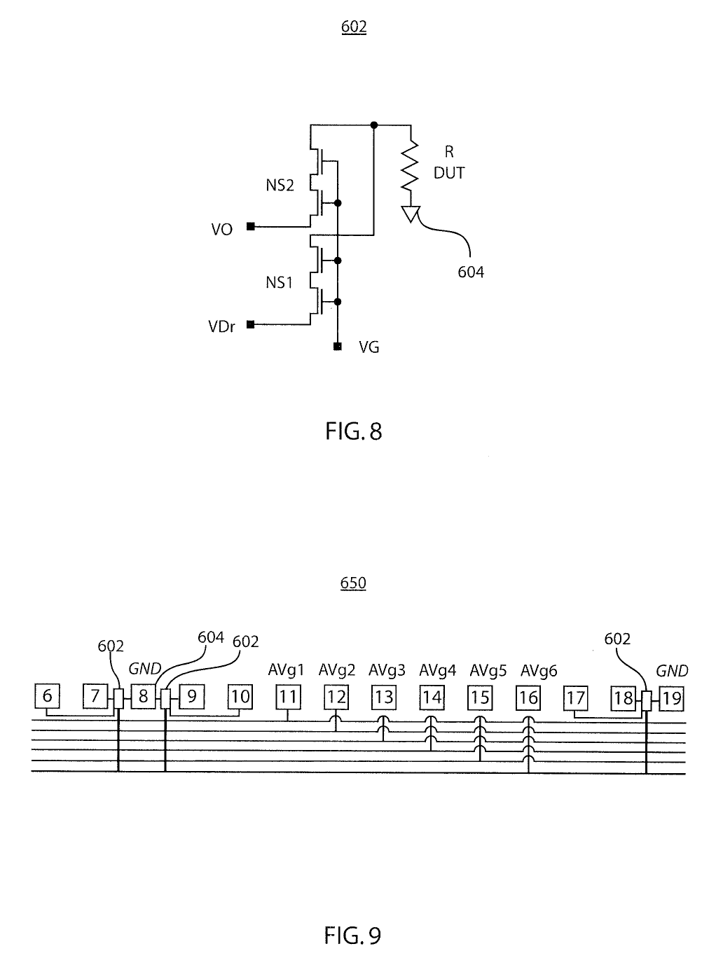

Referring to FIG. 8, an illustrative DUT circuit 602 is shown. Circuit 602 may be tested as a pair of circuits with a common ground (the second circuit is not shown). Circuit 602 may be employed as an element in a MDUT for characterizing linear resistances such as silicon to metal contacts, R DUT. The MDUT includes N of these circuits connected between a ground pad 604 and a voltage force, current measure pad, VDr. A separate output pad VO is provided to read out the voltage across R DUT of the element selected by applying VG=1, while the other elements remain isolated with VG at zero or some small negative potential. The circuit includes n-FET switch pairs NS1 and NS2, which all share a gate node (VG).

Referring to FIG. 9 with continued reference to FIG. 8, in this case, a macro section 650 includes five test pads including pads 7, 8 and 9 which share a ground (GND) pad 8 between a pair of MDUTs 602 (left side of padset), and including pads 18 and 19 for an individual MDUT 602 (right side). VG pads 6, 10 and 17 are provided to service the respective MDUTs 602. The pads of FIG. 9 correspond to the terminals in FIG. 8 and may include a ground pad (GND) 604; voltage pads (voltage force) current measure pads (VDr); and voltage measure pads (VO). Compared to the case of FETs as a DUT, only three pads are needed (one common source pad (VS) and two (voltage force) current measure (VD) pads.

The macro 650 may include a 1 by 25 padset macro with resistor MDUTs 602. Pads 11 to 16 are control inputs for the switches NS1 and NS2. If an additional 5 pad/2 MDUT is added on the left and another on the right, along with a substrate contact, a total of 7 resistor MDUTs 602, each with 6 DUTs can be accommodated.

It should be understood that unlike arrays with decoder addressing, a same basic test structure template in accordance with the present principles works for any device type, and it is preferable that the whole macro is devoted to that device type. For example, a macro template can be dedicated to thick oxide nFETs and tested over the full range of voltages. This cannot be easily done in a decoder addressed array with a decoder comprised of standard oxide thickness devices. The decoder addressing scheme would need a decoder comprised of thick oxide MOSFETs which would need a significant additional design effort and would likely not fit in the available area between pads. In many cases, different macro templates would be needed for different device types which would require many different macro templates.

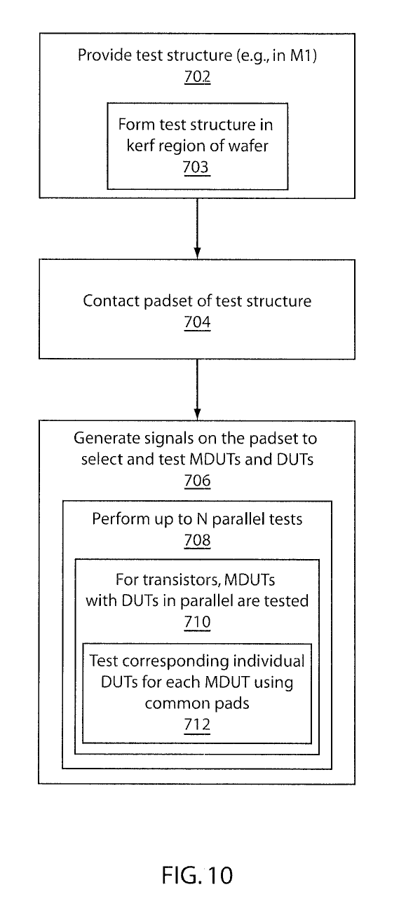

Referring to FIG. 10, a method for testing a test structure is illustratively shown. In block 702, a test structure having a plurality of pads of a padset and parallel wiring connecting the pads with components in the test structure is provided. All that is needed to test the devices present in the MDUTs are the devices themselves, no other active devices are needed within the MDUT to test the MDUT. A metal layer is formed and patterned with a first metal layer (M1) during an integrated circuit process for an integrated circuit device for which the test structure is provided. The test structure is preferably formed concurrently on a wafer with other devices. The test structure may be formed concurrently with product chips so that the test structure tests accurately reflect the testing of the product chips. In block 703, the test structure may be formed in a kerf region of a wafer to conserve wafer area for product chips.

In block 704, the pads are contacted by probes for testing multiple device under test units (MDUTs or md-units), the MDUTs each including a plurality of devices under test (DUTs). The probes may be parts of a parallel testing device or other testing apparatus. In block 706, signals are generated on the pads. Note that the DUT to be measured within an MDUT is selected with a corresponding lead. A magnitude of this signal is also a component of the measurement being made, along with other potentials (e.g., the source and drain potentials). The signals may be generated by the tester and MDUTs, and DUTs are selectively enabled/disabled depending on the pad selection and its corresponding signal. Each of N MDUTs are selected such that a first set of the plurality of pads are employed for enabling testing of each MDUT and a second set of the plurality of pads are designated for testing individual DUTs associated with the enabled MDUTs.

In block 708, up to N parallel tests may be concurrently performed on the DUTs. In one embodiment, one MDUT is selected using the generated signals and then all of the DUTs are tested sequentially for that MDUT. Then, a next MDUT is selected and each of the DUTs are tested for that MDUT using the same corresponding pads. Alternatively, all N MDUTs can be measured in parallel, e.g., a same DUT in all MDUTs is tested, then a next DUT in all MDUTs is tested, etc. until all desired DUTs are tested. Other testing sequences are also contemplated.

In blocks 710 and 712, the DUTs may include transistors and the MDUT includes a plurality of DUTs connected in parallel. In block 710, testing of each MDUT is enabled by generating signals on the first set of the plurality of pads to make connections to a source pad and a drain pad for that MDUT. The source pad and the drain pad are commonly connected to all DUTs of the MDUT being tested.

In block 712, testing of the DUTs on an MDUT is enabled by generating signals on the second set of the plurality of pads to make a connection to a gate pad for each DUT to test individual DUTs for each corresponding MDUT. The DUT may include a circuit having one or more components, the one or more components are concurrently tested. The components may include circuits, p-FETs, n-FETs, etc.

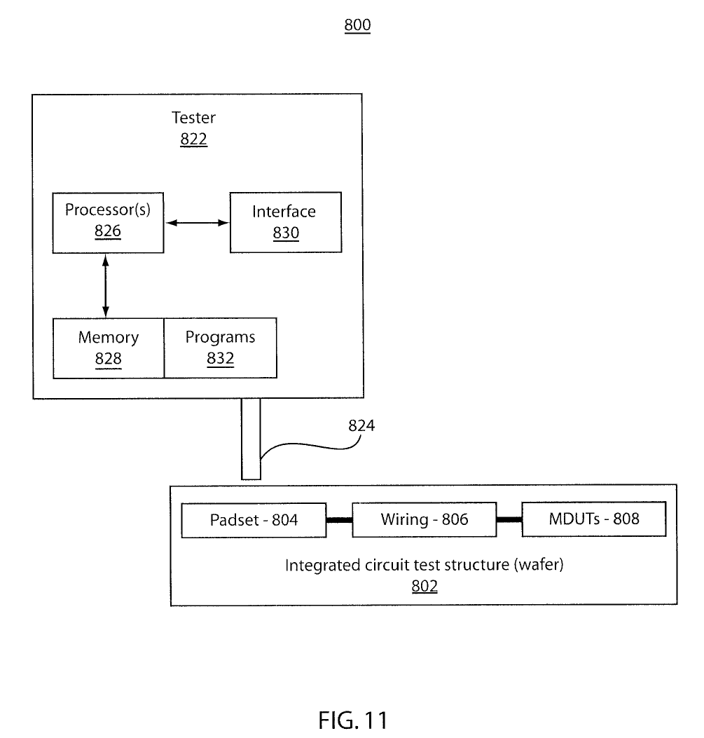

Referring to FIG. 11, a system 800 for testing an integrated test structure is illustratively shown. System 800 includes a test structure (e.g., an integrated circuit chip wafer) 802 having a padset 804 formed thereon. The padset 804 includes a single layer of wiring 806 coupling the padset 804 to a plurality of MDUTs 808. The MDUTs include a plurality of DUTs which may include single devices, such as transistors or other active components in combination passive components, etc.

A parallel tester 822 includes contacts or probes 824 which form electrical connections with the padset 804. The tester 822 is programmed to permit appropriate signal generation to perform parallel device testing on the test structure 802. The parallel tester 822 may include one or more processors 826 and memory 828. The memory may store a test program or programs 832 which execute the test patterns and the signal generation. An interface 830 may include a keyboard, mouse, touchscreen, display, etc. to permit user interactions with the tester 822.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing. Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The test structure as described herein may be part of a design for an integrated circuit chip. The chip design may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Having described preferred embodiments for test structure for parallel test implemented with one metal layer (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. An integrated test circuit, comprising:
a plurality of pads of a padset for testing multiple device under test units (MDUTs), the MDUTs each including a plurality of devices under test (DUTs); and
a first integrated test circuit metal layer patterned to connect the pads to N MDUTs such that a first set of the plurality of pads are employed for enabling testing of each MDUT and a second set of the plurality of pads are designated for testing individual DUTs associated with the enabled MDUTs such that N parallel tests may be concurrently performed.

2. The circuit as recited in claim 1, wherein the DUTs include transistors and the MDUT includes a plurality of DUTs connected in parallel.

3. The circuit as recited in claim 2, wherein the first set of the plurality of pads includes connections to a source pad and a drain pad for each MDUT, where the source pad and the drain pad are common for all DUTs of that MDUT.

4. The circuit as recited in claim 2, wherein the second set of the plurality of pads includes a connection to a gate pad for each DUT, the second set of the plurality of pads for testing individual DUTs for each corresponding MDUT.

5. The circuit as recited in claim 1, wherein a number of DUTs varies with a square of a number of pads.

6. The circuit as recited in claim 1, wherein the first integrated test circuit metal layer corresponds to a first metal layer of an integrated circuit process for an integrated circuit device being tested.

7. The circuit as recited in claim 1, wherein the DUT includes a circuit having one or more components.

8. The circuit as recited in claim 7, wherein the circuit includes components for testing contact resistance.

9. A system for testing integrated circuits, comprising:
a plurality of pads of a padset for testing N multiple device under test units (MDUTs), the MDUTs each including a plurality of devices under test (DUTs);
parallel wiring formed in a first metal layer and configured to selectively enable each MDUT through a first set of the plurality of pads, the parallel wiring further configured to enable individual DUT tests through a second set of the plurality of pads; and
a parallel tester configured to generate signals on the padset such that in conjunction with the parallel wiring, N parallel tests may be concurrently performed.

10. The system as recited in claim 9, wherein the DUT includes a transistor and the MDUT includes a plurality of DUTs connected in parallel.

11. The system as recited in claim 10, wherein the first set of the plurality of pads includes connections to a source pad and a drain pad for each MDUT, where the source pad and the drain pad are common for all DUTs of that MDUT.

12. The system as recited in claim 10, wherein the second set of the plurality of pads includes a connection to a gate pad for each DUT, the second set of the plurality of pads for testing individual DUTs for each corresponding MDUT.

13. The system as recited in claim 9, wherein a number of DUTs varies with a square of a number of pads.

14. The system as recited in claim 9, wherein the first metal layer corresponds to a first metal layer of an integrated circuit process for an integrated circuit device being tested.

15. The system as recited in claim 9, wherein the DUT includes a circuit having one or more components.

16. The system as recited in claim 15, wherein the circuit includes components for testing contact resistance.

17. The system as recited in claim 9, wherein the parallel tester generates signals for controlling pads not being tested.

18. A method for testing a test structure, comprising:
contacting a plurality of pads of a padset for testing multiple device under test units (MDUTs), the MDUTs each including a plurality of devices under test DUTs;
generating signals to a first integrated test circuit metal layer patterned to connect the pads to test N MDUTs such that a first set of the plurality of pads are employed for enabling testing of each MDUT and a second set of the plurality of pads are designated for testing individual DUTs associated with the enabled MDUTs; and
concurrently performing N parallel tests to test the DUTs.

19. The method as recited in claim 18, wherein the DUT includes a transistor and the MDUT includes a plurality of DUTs connected in parallel, the method further comprising enabling testing of each MDUT by generating signals on the first set of the plurality of pads to make connections to a source pad and a drain pad for that MDUT, the source pad and the drain pad being commonly connected to all DUTs of that MDUT.

20. The method as recited in claim 18, wherein the DUT includes a transistor and the MDUT includes a plurality of DUTs connected in parallel, the method further comprising enabling testing of the DUTs on an MDUT by generating signals on the second set of the plurality of pads to make a connection to a gate pad for each DUT, to test individual DUTs for each corresponding MDUT.

21. The method as recited in claim 18, wherein the first integrated test circuit metal layer is formed and patterned with a first metal layer during an integrated circuit process for an integrated circuit device for which the test structure is provided.

22. The method as recited in claim 18, wherein the DUT includes a circuit having one or more components, the method further comprising testing the one or more components.

23. The method as recited in claim 18, further comprising forming the test structure in a kerf region of a wafer.
